(19) United States
(12) Patent Application Publication
(10) Pub. No.: US 2012/0255765 A1
(43) Pub. Date: Oct. 11, 2012

(54) ELECTRODE AND METHOD FOR MANUFACTURING THE SAME

(75) Inventor: MASAKATSU KUROKI, Kanagawa (JP)

(73) Assignee: E I DU PONT DE NEMOURS AND COMPANY, Wilmington, DE (US)

(21) Appl. No.: 13/530,472

(22) Filed: Jun. 22, 2012

Related U.S. Application Data
(63) Continuation of application No. 12/576,328, filed on Oct. 9, 2009.

(51) Int. Cl. H01B 3/10; B05D 3/02; B05D 5/12; H05K 1/03; G03F 7/20

(52) U.S. Cl. 174/255; 174/110 A; 430/319; 427/123

(57) ABSTRACT

Disclosed is an electrode, including a conductive layer containing a conductive component selected from the group consisting of copper, nickel, iron, cobalt, titanium, lead, aluminum, tin, and alloys comprising one of these metals as the principal ingredient thereof, and an oxidation protection layer containing boron oxide, said oxidation protection layer covering the top surface of the conductive layer, or covering both the top surface and the sides of the conductive layer, or covering all locations where the conductive layer has been formed; the electrode being formed by air firing the conductive layer and the oxidation protection layer simultaneously.

This application is a continuation of Ser. No. 12/576,328, filed on Oct. 9, 2009.

### BACKGROUND OF THE INVENTION

1. Field of the Invention

The present invention relates to an electrode of an electric device, and more particularly to improvements in the structure of the electrode.

2. Technical Background

Methods wherein a conductive paste is used as the raw material of an electrode are widely known. The conductive paste generally comprises a conductive component, glass frit, organic binder, and solvent. Photosensitive paste, which enables fine pattern formation, is also widely used, and the composition of the photosensitive paste generally includes monomer and photoinitiator in addition to the aforementioned components.

Non-photosensitive paste is coated in a predetermined pattern by screen printing or another method, and an electrode consisting of glass with a conductive component and binder is formed therefrom by drying and firing. Photosensitive paste (negative type) is exposed through a mask after it is coated. Polymerization of the monomer progresses at the exposed sites, and thereafter an electrode consisting of glass with a conductive component and binder is formed by developing the photosensitive paste and firing.

Silver is generally used as the conductive component (e.g., U.S. Pat. No. 5,047,313 and US Patent Publication 2005/0287472). Capital investment for the furnace can be decreased because precious metals such as gold, silver, and palladium can be sintered in air. Using precious metals, however, invites a sharp rise in material costs because precious metals are expensive.

Copper is widely used as a conductive component in semiconductor circuits and the like. Copper has the advantage of being cheaper than silver. However, copper cannot be sintered in air because it oxidizes easily, and this increases capital investment because firing under a nitrogen atmosphere and the like is required.

A method using boron together with metal powder has been disclosed as technology that enables air firing of an easily oxidizable metal in a non-photosensitive paste (U.S. Pat. No. 4,122,232). In the examples of U.S. Pat. No. 4,122,232, copper powder finer than 325 mesh is used. The average particle size of the copper powder is not specifically described, but the average particle size of copper powder sorted using a 325 mesh is generally 40 to 50 μm. Boron oxide (B₂O₃), that is produced as a result of firing, has a high resistance value, and this increases the resistance of the formed electrode. Therefore, technology has been sought that will keep the resistance down in an electrode formed by the air firing of a paste comprising a conductive component, such as copper powder, etc., and that is less expensive than silver.

### SUMMARY OF THE INVENTION

The invention provides an electrode which is formed by air firing, and has low resistance, although comprising a conductive component that might be easily oxidized in an air firing process.

An electrode with the above characteristics can be achieved by configuring a paste comprising boron powder as the top layer of an electrode containing copper powder, another easily oxidizable metal, or an alloy thereof as the conductive component.

The present invention discloses an electrode comprising: a conductive layer containing a conductive component selected from the group consisting of copper, nickel, iron, cobalt, titanium, lead, aluminum, tin, and alloys comprising one of these metals as the principal ingredient thereof; and an oxidation protection layer containing boron oxide and covering the top surface of the conductive layer or covering the top surface and sides of the conductive layer or covering any and all locations upon which the conductive paste has been coated. Furthermore, the electrode is formed by air firing the conductive layer and the oxidation protection layer simultaneously.

The present invention is also a method for manufacturing an electrode comprising the steps of:

coating a conductive paste containing a conductive component selected from the group consisting of copper, nickel, iron, cobalt, titanium, lead, aluminum, tin, and alloys comprising one of these metals as the principal ingredient thereof, onto a substrate in a predetermined pattern;

drying the conductive paste; coating a boron paste containing boron powder on top of the dried conductive paste; drying the boron paste; and

air firing the conductive paste and boron paste.

Furthermore, the present invention is a method for manufacturing an electrode comprising the steps of:

coating a photosensitive conductive paste containing a conductive component selected from the group consisting of copper, nickel, iron, cobalt, titanium, lead, aluminum, tin, and alloys comprising one of these metals as the principal ingredient thereof, onto a substrate;

exposing the coated conductive paste in a predetermined pattern;

developing the exposed conductive paste;

coating a boron paste containing boron powder on top of the developed conductive paste;

drying the boron paste; and

air firing the conductive paste and boron paste.

In addition, the present invention is a method for manufacturing an electrode comprising the steps of: coating a conductive paste containing a conductive component selected from the group consisting of copper, nickel, iron, cobalt, titanium, lead, aluminum, tin, and alloys comprising one of these metals as the principal ingredient thereof, onto a substrate; drying the conductive paste; coating a photosensitive boron paste containing boron powder on top of the dried conductive paste; exposing the coated photosensitive boron paste in a predetermined pattern; developing the conductive paste and exposed boron paste; and air firing the conductive paste and boron paste.

The present invention enables the formation of a low-resistance pattern by air firing using an inexpensive conductive component. The present invention will contribute to a decrease in the cost of producing an electrode for an electronic device.

### BRIEF DESCRIPTION OF THE DRAWINGS

FIG. 1 is a cross-sectional schematic drawing of the first embodiment of the electrode of the present invention;

FIG. 2 is a cross-sectional schematic drawing of the second embodiment of the electrode of the present invention;

FIG. 3 is a cross-sectional drawing of the third embodiment of the electrode of the present invention;

FIG. 4 is a cross-sectional schematic drawing explaining the first embodiment of the manufacturing method of the present invention;

FIG. 5 is a cross-sectional schematic drawing explaining an embodiment wherein the coating pattern of a boron paste is modified;

FIG. 6 is a cross-sectional schematic drawing explaining a different embodiment wherein the coating pattern of the boron paste is modified;

FIG. 7 is a cross-sectional schematic drawing explaining the second embodiment of the manufacturing method of the present invention; and

FIG. 8 is a cross-sectional schematic drawing explaining the third embodiment of the manufacturing method of the present invention.

### DETAILED DESCRIPTION OF THE INVENTION

In the electrode of the present invention, at least the top of the surface of the conductive paste containing an easily oxidizable conductive component such as copper is covered with the boron paste containing boron powder prior to firing. As a result, even though firing is carried out in air, oxidation of the copper is inhibited by the boron paste, and a low-resistance electrode is formed.

The formed electrode becomes a laminate comprising the conductive layer containing a conductive component such as copper, nickel, etc., and the oxidation protection layer containing boron oxide that covers the top surface of the conductive layer. The electrode of the present invention is described below with reference to the drawings.

FIG. 1 is a cross-sectional schematic drawing of the first embodiment of the electrode of the present invention. A conductive layer 20 containing a conductive component is formed on top of a substrate 10. An oxidation protection layer 30 containing boron oxide lies on top of the conductive layer 20. The paste that forms the oxidation protection layer 30 contains boron, and after the firing step, the oxidation protection layer 30 contains oxidized boron oxide. In FIG. 1 only the top surface of the conductive layer 20 is covered with the oxidation protection layer 30 and the sides thereof is exposed. As a result, oxidation of the conductive component contained in the conductive layer 20 progresses during firing in the sides thereof. However, because the top surface that accounts for most of the surface area is protected by the oxidation protection layer 30, an increase in electrode resistance due to oxidation of the conductive component therein is controlled.

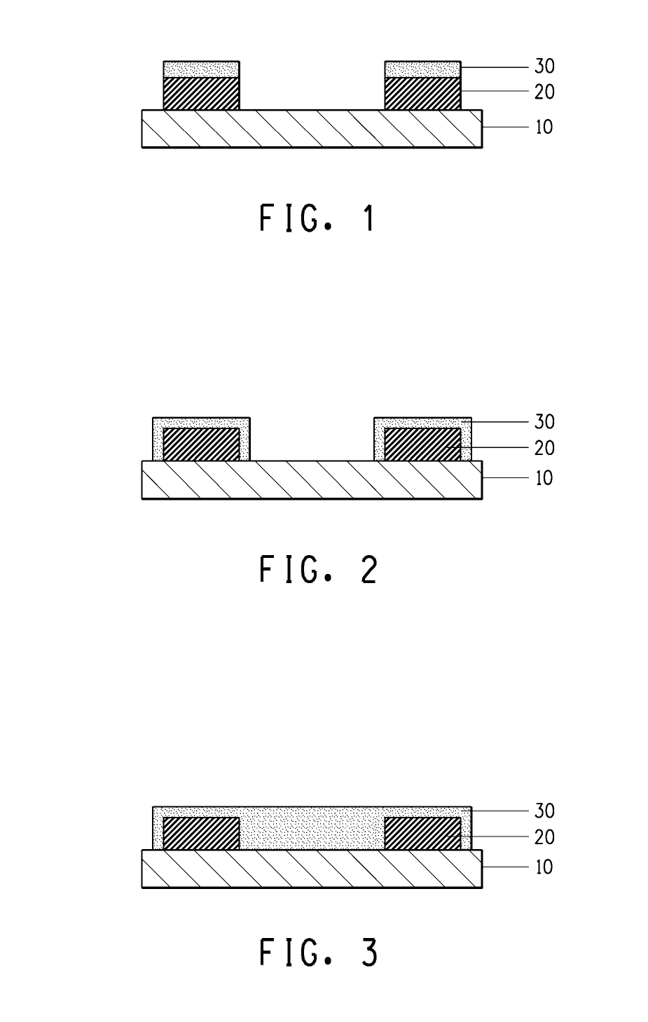

Oxidation of the conductive component via the sides of the conductive layer can be prevented by covering the sides with an oxidation protection layer. FIG. 2 is a cross-sectional schematic drawing of a second embodiment of the electrode of the present invention. As shown in the electrode illustrated in FIG. 2, oxidation of the conductive component via the sides of the conductive layer is inhibited by also covering those sides, and that enables the resistance of the electrode to be decreased even more.

Methods of covering the sides of the conductive layer with the oxidation protection layer are described in detail below, but a mode wherein the boron paste is coated wider than the width of the conductive layer pattern can be noted as an example. The pattern of boron paste is coated wider than the pattern of the conductive layer 20. The parts extending beyond the conductive layer 20 droop toward the substrate 10 due to gravity. As a result, an electrode is formed wherein the sides of the conductive layer 20 are covered with the oxidation protection layer 30. For ease of explanation, in FIG. 2 the thickness of the oxidation protection layer 30 formed on the top surface of the conductive layer 20 is depicted as identical to the thickness of the oxidation protection layer 30 formed on the sides of the conductive layer 20, but when protecting the sides in the above manner, the oxidation protection layer is often thinner on the sides than on the top. If the amount of drooping paste is large, the oxygen protection layer formed on the sides becomes thicker as it approaches the substrate. On the other hand, if the amount of drooping paste is small, the oxidation protection layer becomes thinner as it approaches the substrate. Oxidation of the conductive component via the sides can be inhibited under both circumstances.

The mode shown in FIG. 3 can be noted as a different method of covering the sides of the conductive layer with the oxidation protection layer. FIG. 3 is a cross-sectional schematic drawing of the third embodiment of the electrode of the present invention. In FIG. 3 an oxidation protection layer 30 is formed so that it covers the entire conductive layer 20 formed on the substrate 10. In other words, rather than forming an oxidation protection layer matching the pattern of the conductive layer 20, an oxidation protection layer is formed with a size matching the size of the substrate. When the oxidation protection layer is coated in this manner, oxidation of the conductive component of the conductive layer is inhibited well, and because alignment with the pattern of the conductive layer is not necessary, the oxidation protection layer is easily formed. It should be noted, however, that the amount of boron paste raw material used for this oxidation protection layer is greater than in the case of FIG. 2.

Next the method for manufacturing the electrode of the present invention is explained. The first embodiment of the manufacturing method is a case wherein neither the conductive paste nor the boron paste is photosensitive. The second embodiment of the manufacturing method is a case wherein the conductive paste is photosensitive, and the boron paste is not photosensitive. The third embodiment of the manufacturing method is a case wherein the boron paste is photosensitive. In the third embodiment, the conductive paste can be either photosensitive or not photosensitive.

First the conductive component of the conductive paste, boron powder of the boron paste, glass fit, solvent, organic polymer binder, photo polymerization monomer, and photo polymerization initiator are described, and then each manufacturing method is fully explained.

### (I) Conductive Component

Copper, nickel, iron, cobalt, titanium, lead, aluminum, tin, and alloys comprising one of these metals as the principal ingredient thereof can be noted as the conductive component. Herein “principal ingredient” refers to a component that constitutes 40% or more by weight and is the component in the alloy with the highest content ratio. Two or more types thereof can be used in combination.

Concrete examples of such an alloy include those wherein the principal ingredient is tin such as a Sn—Cu—Ag alloy, those wherein the principal ingredient is copper such as a Cu—Sn—Ni—P alloy, those wherein the principal ingredient is aluminum such as an Al—Si alloy, and those wherein the principal ingredient is lead such as a Pb—Sn alloy.

The conductive component is added to provide conductivity. Its average diameter is, but is not limited to, preferably less than 30 μm, more preferably less than 20 μm, and even more preferably less than 10 μm. The lower limit of the diameter is not particularly restricted; however, from the viewpoint of material cost, a conductive component greater than 0.1 μm in average diameter is preferable.

The average diameter is obtained by measuring the distribution of the particle diameters by using a laser diffraction scattering method and can be defined as D50. Microtrac model X-100 is an example of the commercially-available devices therefore.

An electrode with low resistance can be formed by using a conductive component with a fine particle size. There has been a problem when a fine conductive component is used because oxidation proceeds when air firing is carried out and as a result, the resistance of the electrode increases. The electrode resistance is decreased in the present invention by the use of a fine conductive component.

The form of conductive component is not particularly limited. It can be in spherical or flake form. However, the spherical form is preferable in the photosensitive paste.

A metal other than the above conductive component can be contained in the photosensitive paste, but from the standpoint of reducing the cost of raw materials, preferably the amount of a precious metal such as silver, gold, or palladium is low. Specifically, the total amount of precious metal is preferably less than 30 wt %, more preferably less than 15 wt %, still more preferably less than 5 wt %, even more preferably less than 1 wt %, and most preferably, the precious metal is not substantially contained therein. Herein the term “not substantially contained” is a concept that encompasses cases in which a precious metal is unintentionally contained as an impurity.

### (II) Boron Powder

Boron powder is used to prevent oxidation of the conductive component during firing. The increase in electrode resistance resulting from the oxidation of the conductive component can be inhibited by adding boron powder to the paste.

The average particle diameter is preferably less than 3 μm, and more preferably 2 μm. The average diameter is obtained by measuring the distribution of the particle diameters by using a laser diffraction scattering method and can be defined as D50. Microtrac model X-100 is an example of the commercially-available devices therefrom. The lower limit of the diameter is not particularly restricted; however, from the viewpoint of material cost, boron powder greater than 0.1 μm in average diameter is preferable.

The use of boron powder of a small particle size is effective when forming a thin electrode. When a thin electrode with a film thickness of 1 to 4 μm is formed, the use of boron powder with a large particle size causes deterioration in the appearance of film quality at the time of development. The electrode appearance can be excellently conserved by using boron powder with the small particle size stipulated above.

### (III) Glass Frit

Glass fit can increase the sealing property of the composition with a substrate, e.g., the glass substrate used for the rear panel of PDP.

Types of glass frit include bismuth-based glass frit, boric acid-based glass frit, phosphorus-based glass fit, Zn—B based glass frit, and lead-based glass frit. The use of lead-free glass frit is preferred in consideration of the burden imposed on the environment. Glass fit can be prepared by methods well known in the art. For example, the glass component can be prepared by mixing and melting raw materials such as oxides, hydroxides, carbonates etc, forming a cullet therefrom by quenching, and then performing mechanical pulverization (wet or dry milling). Thereafter, if needed, sorting is carried out to the desired particle size.

The softening point of the glass frit is normally to be 325 to 700° C., preferably 350 to 650° C., and more preferably 550 to 600° C. If melting takes place at a temperature lower than 325° C., the organic substances will tend to become enveloped, and subsequent degradation of the organic substances will cause blisters to be produced in the paste. A softening point over 700° C., on the other hand, will weaken paste adhesion and may damage the glass substrate. The specific surface area of the glass frit is preferably no more than 10 m²/g. The average diameter is generally 0.1-10 μm. Preferably, at least 90 wt % of the glass frit has a particle diameter of 0.4 to 10 μm.

Next, organic components of photosensitive paste are described. Photo polymerization initiator, monomer, and organic vehicle are typical organic components. Usually, organic vehicle contains organic polymer binder and solvent.

### (IV) Photo Polymerization Initiator

Photo polymerization initiator is used for photo-polymerizing the photo polymerization-type monomer. The photo polymerization initiator is preferably thermally inactive at 185° C. or lower, but it generates a free radical when it is exposed to UV rays. Examples of the photo polymerization initiator include compounds having two intramolecular rings in a conjugated carbocyclic ring system. This type of compound includes substituted or non-substituted multinuclear quinone.

Practically, examples of quinone include: ethyl 4-dimethyl aminobenzoate, diethylthioxanthone, 9,10-anthraquinone, 2-methylanthraquinone, 2-ethylanthraquinone, 2-t-butylanthraquinone, octamethylanthraquinone, 1,4-naphtoquinone, 9,10-phenanthrenequinoen, benzo[a]anthracene-7,12 dione, 2,3-naphtacene-5,12-dione, 2-methyl-1,4-naphtoquinone, 1,4-dimethylanthraquinone, 2,3-dimethylanthraquinone, 2-phenylanthraquinone, 2,3-diphenylanthraquinone, retenequinone, 7,8,9,10-tetrahydronaphtacene-5,12-dione and 1,2,3,4-tetrahydrobenzo[a]anthracene-7,12-dione. Other compounds that may be used include those given in U.S. Pat. Nos. 2,760,863, 2,850,445, 2,875,047, 3,074,974, 3,097,097, 3,145,104, 3,427,161, 3,479,185, 3,549,367, and 4,162,162.

### (V) Photo Polymerization Monomer

The photo polymerization monomer is not particularly limited herein. Examples include ethylenic unsaturated compounds having at least one polymerizable ethylene group. Preferably, the photosensitive paste contains at least one multi-point crosslinking monomer with 3 or more linking groups.

Examples of the preferred monomer include: (metha)acrylic acid t-butyl, 1,5-pentandiol di(metha)acrylate, (metha)acrylic acid N,N-dimethylaminoethyl, ethyleneglycol di(metha)acrylate, 1,4-butanediol di(metha)acrylate, diethyleneglycol di(metha)acrylate, hexamethyleneglycol di(metha)acrylate, 1,3-propanediol di(metha)acrylate, decamethyleneglycol di(metha)acrylate, 1,4-cyclohexanediol di(metha)acrylate, 2,2-dimethylolpropane di(metha)acrylate, glycerol di(metha)acrylate, tripropyleneglycol di(metha)acrylate, glycerol tri(metha)acrylate, trimethylolpropane tri(metha)acrylate, trimethylolpropane ethoxy triacrylate, the compound disclosed in U.S. Pat. No. 3,380,381, 2,2-di(p-hydroxyphenyl)-propane di(metha)acrylate, pentaetythritol tetra(metha)acrylate, dipentaerythritol pentaacrylate, dipentaerythritol tetraacrylate, triethyleneglycol diacrylate, polyoxyetyl-1,2-di-(p-hydroxyetyl)propane dimethacrylate, bisphenol-A di-[3-(metha)acryloxy-2-hydroxypropyl]ether, bisphenol-A di-[2-(metha)acryloxyetyl]ether, 1,4-butanediol di-(3-methacryloxy-2-hydroxypropyl)ether, triethyleneglycol dimethacrylate, polyoxypropyl trimethylolpropane triacrylate, butyleneglycol di(metha)acrylate, 1,2,4-butanediol tri(metha)acrylate, 2,2,4-trimethyl-1,3-pentanediol di(metha)acrylate, 1-phenylethylene-1,2-dimethacrylate, fumaric diallyl, styrene, 1,4-benzenedioldimethacrylate, 1,4-diisopropenylbenzene and 1,3,5-triisopropenylbenzene. Here, (metha)acrylate represents both acrylate and methacrylate.

### (VI) Organic Polymer Binder

An organic binder is used to allow constituents such as the conductive powder, boron powder and glass fit to be dispersed in the composition. The organic polymer binder is used for improving the coating property and stabilization of the coating film when the conductive paste is coated on a substrate in screen printing or related technology by using a known method. The organic polymer binder is removed when the electrodes are formed by sintering the photosensitive paste.

The organic binder is not particularly limited herein provided it dissolves in the desired solvent and provides a preferable viscosity. Examples include a cellulose derivative such as ethyl cellulose; acetyl cellulose, a polyacrylic ester; polymethacrylic ester; polystyrene; vinyl polymer such as polyvinyl acetate, polyvinyl butyral, and the like; polyurethane; polyester; polyether; polycarbonate; and copolymers thereof.

When lines are formed with a developing solution such as water or alkaline solution, it is preferable to select as the binder polymer one that will expand and dissolve in the developer. For example, when water and an alkaline solution are used for the development process, hydroxypropyl cellulose, and a binder polymer having a carboxyl group on a side chain, e.g., a copolymer of methylmethacrylate and methacrylic acid, can be used.

When the coated and dried photosensitive paste is developed with an aqueous developing fluid and its patterns are formed, it is preferable to use the organic polymer binder which has high resolution in light of the development capability of the aqueous developing fluid. Examples of the organic polymer binder which can meet this condition include those that contain non-acidic comonomer or acidic comonomer. Copolymers or interpolymers (mixed polymers) are also preferable. Other examples of organic polymer binder are an acrylic polymer binder or other polymer binders shown in US Patent Publication 2007/0001607.

### (VI) Solvent

The primary purpose for using an organic solvent is to allow the dispersion of solids contained in the composition to be readily applied to the substrate. As such, first of all the organic solvent is preferably one that allows the solids to be dispersed while maintaining suitable stability. Secondly, the rheological properties of the organic solvent preferably impart favorable application properties to the dispersion.

The organic solvent may be a single component or a mixture of organic solvents. The organic solvent that is selected is preferably one in which the polymer and other organic components can be completely dissolved. The selected organic solvent is preferably one that is inert to the other ingredients in the composition. The organic solvent preferably has sufficiently high volatility, and preferably can evaporate from the dispersion even when applied in air at a relatively low temperature. Preferably the solvent is not so volatile that the paste on the screen will dry too rapidly at ordinary temperature during the printing process. The boiling point of the organic solvent at ordinary pressure is preferably no more than 300° C., and more preferably no more than 250° C.

Specific examples of organic solvents include aliphatic alcohols and esters of those alcohols such as acetate esters or propionate esters; terpenes such as turpentine, α- or β-terpineol, or mixtures thereof; ethylene glycol or esters of ethylene glycol such as ethylene glycol monobutyl ether or butyl cellosolve acetate; butyl carbitol or esters of carbitol such as butyl carbitol acetate and carbitol acetate; and Texanol (2,2,4-trimethyl-1,3-pentanediol monoisobutyrate).

### (VII) Additional Elements

Additional elements known to those skilled in the art such as dispersing agent, stabilizer such as TAOBN (1,4,4-trimethyl-2,3-diazabicyclo[3.2.2]-non-2-ene-N,N-dixoide) and malonic acid, plasticizer, parting agent, stripping agent, dispersant, defoamer such as silicone oil, and moistening agent can be present in the photosensitive paste. Appropriate elements may be selected based on conventional technology.

To formulate the photosensitive paste, a vehicle of each element is formulated by using organic elements and solvent as may be necessary, which is then mixed with conductive powder and glass fit. After that, the obtained mixture is kneaded by using a sand mixer, such as a roll mixer, mixer, homogeneous mixer, ball mill and bead mill, thereby obtaining the photosensitive paste.

The content of each component is adjusted depending on whether it imparts photosensitivity to the paste and whether it imparts conductivity to the paste. Table 1 shows a summary of the general content of each component according to the type of the paste. Each numerical value is expressed as the weight ratio (wt %) in relation to the total amount of the paste. The designation “X-X>Y-Y” means that the narrower range of “Y-Y” is preferred over the wider range of “X-X”.

In the table, boron is not an essential component of the conductive paste, and the conductive powder is not an essential component of the boron paste. However, to improve the gloss of the film, and to adjust the photo speed, viscosity of the paste, and printability, a certain amount thereof can be mixed thereinto within a range such that the resistance properties are not adversely affected thereby.

Moreover, initiator and monomer are normally unnecessary for non-photosensitive paste, but a suitable amount thereof can be added to impart flexibility to the film, to facilitate full image exposure, curing of the surface, and handling after coating, to disperse monomer and plasticizer to another layer after coating, etc.

TABLE 1

| | | Photosensitive | | Photosensitive |
|---|---|---|---|---|
| | Conductive paste | conductive paste | Boron paste | boron paste |
| (I) Conductive | 60-96 > 65-90 | 40-75 > 40-70 | Not required | Not required |
| component | | | | |
| (II) Boron | Not required | Not required | 5-50 > 10-40 | 5-30 > 10-25 |
| (III) Glass Frit | 0.1-10 > 0.3-5 | 0.1-10 > 0.3-5 | 0-5 > 0.1-3 | 0-5 > 0.1-3 |
| (IV) Initiator | Not required | 0.2-8 > 0.5-5 | Not required | 0.2-10 > 0.5-6 |
| (V) Monomer | Not required | 0.5-30 > 3-25 | Not required | 0.5-50 > 5-40 |
| (VI) Polymer | 0.5-20 > 1-15 | 3-20 > 4-15 | 3-30 > 5-25 | 3-40 > 8-30 |
| Binder | | | | |
| (VI) Solvent | 0.5-20 > 3-15 | 0.5-35 > 5-30 | 0.5-20 > 3-15 | 0.5-40 > 5-30 |

The first embodiment of the manufacturing method wherein both the conductive paste and the boron paste are not photosensitive will now be described.

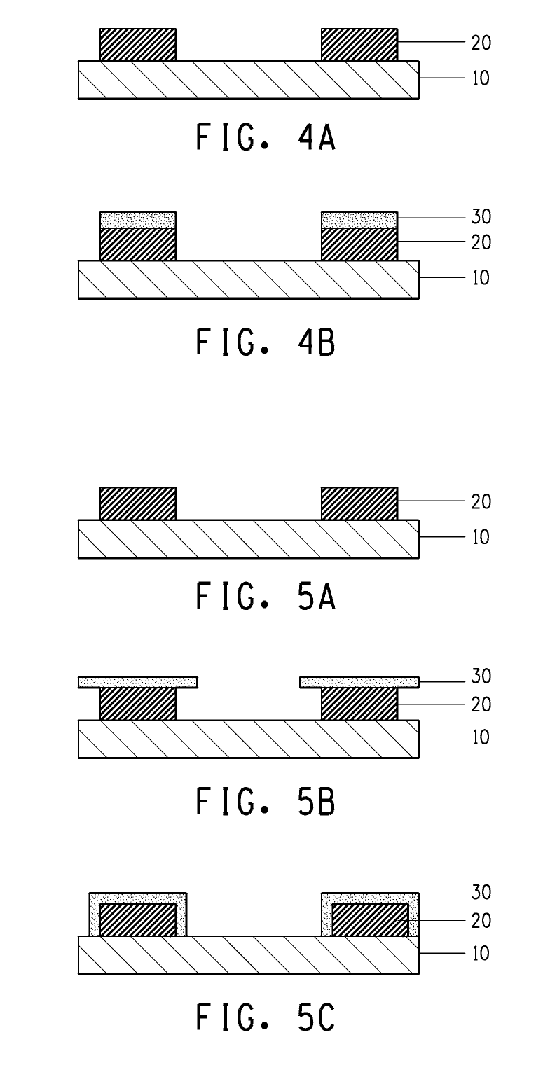

FIG. 4 is a cross-sectional schematic drawing that explains the first embodiment of the manufacturing method of the present invention. First the conductive paste containing the conductive component is coated on the substrate 10 in a predetermined pattern. The substrate is selected depending on the electric device to be manufactured. For example, a glass substrate is used in the case of a rear panel of a PDP. The electrode pattern is not particularly limited herein provided it is designed according to the intended use.

The coating means of the conductive paste is not particularly limited herein. A method widely used in prior art such as screen printing can be used as the conductive paste coating means, and means of advanced development such as inkjet printing can also be used.

The coated conductive paste is dried to form a conductive layer 10, which is later sintered (FIG. 4 (A)). The drying conditions are not particularly limited if the layer of the conductive paste is dried. For example, it may be dried for 18-20 minutes at 100° C. Also, the conductive paste can be dried by using a conveyer-type infrared drying machine. Depending on the circumstances, the conductive paste can be dried by air drying without specific drying equipment.

The boron paste containing the boron powder is coated on top of the conductive paste. Just as with the conductive paste, a method widely used in prior art such as screen printing can be used as the means of coating the boron paste, and means of advanced development such as inkjet printing can also be used.

The coated boron paste is dried to form a layer 20, which is later sintered (FIG. 4 (B)). The drying conditions are not particularly limited if the layer of the conductive paste is dried. For example, it may be dried for 18-20 minutes at 100° C. Also, the conductive paste can be dried by using a conveyer-type infrared drying machine. Depending on the circumstances, the boron paste can be dried by air drying without specific drying equipment.

Next, the conductive paste and the boron paste are sintered. The composition can be sintered in a sintering furnace which has a predetermined temperature profile. The maximum temperature during the sintering process is preferably 400-600° C., or more preferably 500-600° C. The sintering period is preferably 1-3 hours, or more preferably 1.5 hours.

In the present invention firing is carried out in an air atmosphere. As noted above, a low-resistance pattern can be formed even with air firing by forming a layer containing boron on the surface of a conductive layer containing copper. In the present application, “firing in air” or “air firing” essentially refers to firing without replacing the atmosphere in the firing furnace, and more specifically it includes both firing without replacing the atmosphere in the firing furnace and firing with a replacement of 5 vol % or less of the atmosphere in the furnace.

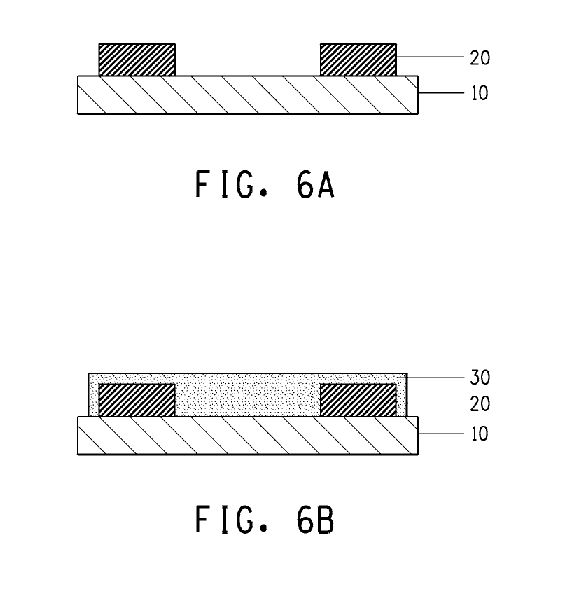

In the first embodiment of the manufacturing method the boron paste coating pattern can be modified as shown in FIG. 5 and FIG. 6.

FIG. 5 is a cross-sectional schematic drawing that explains an embodiment wherein the boron paste coating pattern is modified. First the conductive paste containing the conductive component is coated on the substrate 10 in a predetermined pattern. The coated conductive paste is dried to form a conductive layer 10, which is later sintered (FIG. 5 (A)).

The boron paste containing the boron powder is coated on top of the conductive paste. At this time, as shown in FIG. 5(B), the boron paste is coated in a pattern wider than the width of the conductive layer pattern. For example, if the width of the pattern of the conductive paste is 100 μm, the boron paste is coated 120 μm wide. As a result, the parts of the boron paste extending beyond the conductive paste droop over the dried conductive paste (conductive layer) 20, and the sides of the conductive paste are covered with that part of the boron paste (FIG. 5(C)).

The coated boron paste is dried to form a layer 20, which is later sintered (FIG. 5 (C)), and the conductive paste and the boron paste are sintered simultaneously.

The sides of the conductive layer can be covered with the boron paste by coating the boron paste as shown in FIG. 5. Consequently, oxidation of the conductive layer during firing is inhibited even more.

FIG. 6 is a cross-sectional schematic drawing that explains a different embodiment wherein the boron paste coating pattern is modified. First the conductive paste containing the conductive component is coated on the substrate 10 in a predetermined pattern. The coated conductive paste is dried to form a conductive layer 10, which is later sintered (FIG. 6 (A)).

The boron paste containing the boron powder is coated on top of the conductive paste. At this time, as shown in FIG. 6(B), the boron paste is coated to cover all the locations on which the conductive paste has been coated. When the conductive layer 20 is formed on the substrate 10, normally the pattern does not extend to the edges of the substrate and a certain amount of blank space is present. Therefore it is possible to coat the boron paste so that it covers all locations on which the conductive paste has been coated by coating the boron paste so that the edges of the boron paste coating pattern reach the blank areas.

The coated boron paste is dried to form a layer 20, which is later sintered, and the conductive paste and the boron paste are sintered simultaneously.

The coating pattern of the boron paste can be decided in accordance with the shape of the substrate. For example, if the substrate is 110 cm×63 cm, the paste can be coated in a rectangular pattern slightly smaller than the size of the substrate. If the conductive layer is formed on only part of the substrate, the boron paste can be coated at spots corresponding to the locations at which the conductive layer has been formed. Moreover, if a site is to function as a terminal, the coating pattern can be designed so that the boron paste is not coated thereon in order to provide continuity with the outside.

A first advantage provided by coating the boron paste as shown in FIG. 6 is that oxidation of the conductive component in the conductive layer is inhibited even more. A second advantage is that the same coating pattern can be used irrespective of the pattern of the conductive layer if the substrate is the same size. When the paste is coated by screen printing, for example, it is necessary to prepare a shape that matches the coating pattern. If the boron paste is coated as shown in FIG. 6, however, there is no need to change the shape used to coat the boron paste even if the pattern of the conductive layer is changed.

The second embodiment of the manufacturing method wherein the conductive paste is photosensitive, but the boron paste is not photosensitive will now be described.

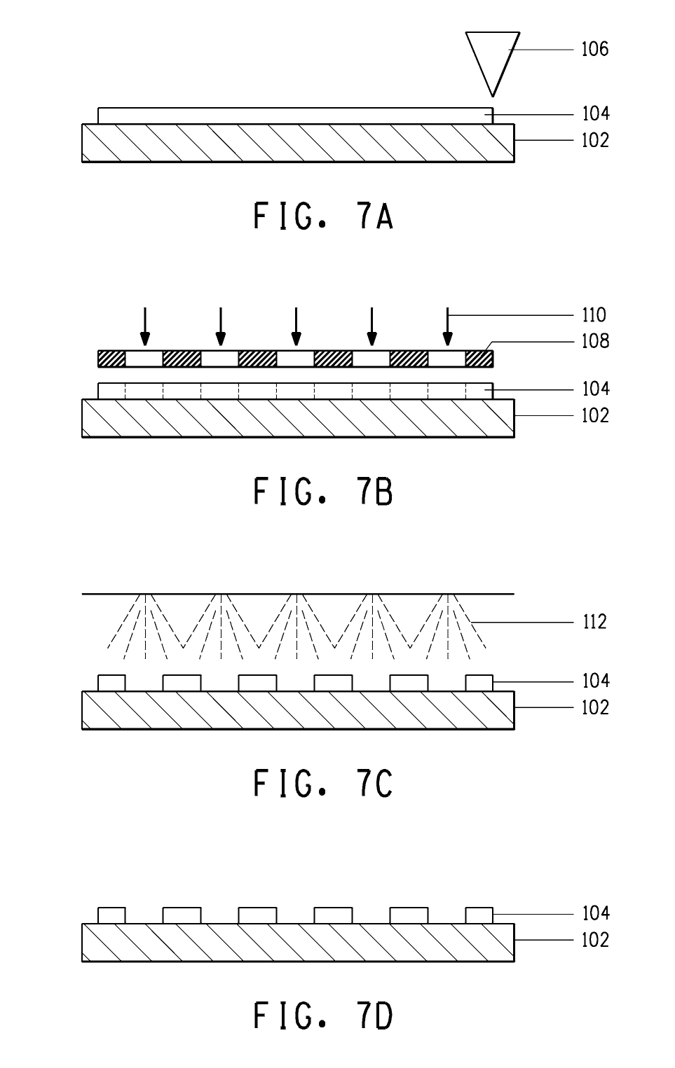

FIG. 7 is a cross-sectional schematic drawing that explains the second embodiment of the manufacturing method of the present invention. FIG. 7 illustrates a mode wherein the pattern is formed by using screen printing, but the means of coating the paste is not limited thereto. Moreover, the method of forming the pattern can be modified as needed.

First, the photosensitive conductive paste is coated on a substrate. Photosensitive conductive paste (104) is fully coated on substrate (102) by screen-printing and a coating method (106) that uses a dispenser (FIG. 7(A)).

Next, the coated photosensitive paste is dried. The drying conditions are not particularly limited if the layer of the photosensitive paste is dried. For example, it may be dried for 18-20 minutes at 100° C. Also, the photosensitive paste can be dried by using a conveyer-type infrared drying machine.

Next, the dried photosensitive paste is patterned. In the patterning treatment, the dried photosensitive paste is exposed and developed. In the exposing process, a photo mask (108) which has electrode patterns is placed on the dried photosensitive paste (104), which is irradiated with ultraviolet rays (110) (FIG. 7(B)).

The exposure conditions differ depending on the type of the photosensitive paste and the film thickness of the photosensitive paste. For example, in an exposure process where a gap of 200-400 μm is used, it is preferable to use ultraviolet rays of 100 mJ/cm² to 2000 mJ/cm². The irradiation period is preferably 5-200 seconds.

The development can carried out using an alkaline solution. As the alkaline solution, 0.4% sodium carbonate solution may be used. The development can be made by spraying alkaline solution (112) to exposed photosensitive paste layer (104) on substrate (102) (FIG. 7(C)) or immersing substrate (102) which has exposed photosensitive paste (104) into the alkaline solution. A conductive layer 104 is formed on the substrate 102 by a process such as disclosed above.

Next the boron paste is coated on the conductive layer 104. The method of coating the boron paste and the coating pattern are those described in the first embodiment of the manufacturing method of the present invention. In other words, all modes of an embodiment wherein the boron paste is coated in the same pattern as the coating pattern of the conductive paste (cf. FIG. 4), an embodiment wherein the boron paste is coated in a pattern that is wider than the coating pattern of the conductive paste and part of the coated boron paste covers the sides of the conductive paste (cf. FIG. 5), and an embodiment wherein the boron paste is coated to cover all locations on which the conductive paste has been coated (cf. FIG. 6) can be used. Various modifications are also possible just as in the first embodiment of the manufacturing method of the present invention.

The third embodiment of the manufacturing method of the present invention wherein the boron paste is photosensitive will now be described. In the third embodiment, the conductive paste can be either photosensitive or not photosensitive.

When both the boron paste and the conductive paste are photosensitive, a process based on the one used in the manufacturing method of a double layer bus electrode for a PDP can be used. For example, the method described in US Patent Publication 2009/0033220 can serve as a reference.

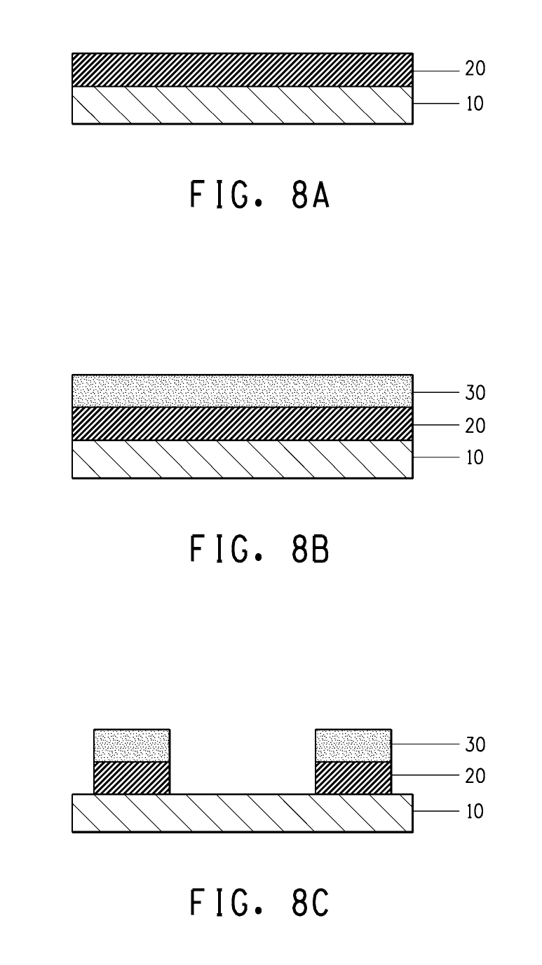

The gist will be briefly described while referring to FIG. 8. FIG. 8 is a cross-sectional schematic drawing that explains the third embodiment of the manufacturing method of the present invention. A photosensitive conductive paste containing a conductive component is coated on the substrate 10 (FIG. 8 (A)). The aforementioned coated conductive paste is then dried. Photosensitive boron paste containing boron powder is coated on top of the dried conductive paste (FIG. 8(B)). Next, the photosensitive boron paste is exposed in a predetermined pattern. The mask shown in FIG. 7(B), for example, is used during the exposure. By controlling the dose and energy so that light also reaches the photosensitive conductive paste, the reaction proceeds in not only the photosensitive boron paste, but also in the photosensitive conductive paste.

The conductive paste and the boron paste are developed to form the predetermined pattern (FIG. 8(C)). Next, the conductive paste and the boron paste are air fired to manufacture an electrode. The firing conditions have already been described above, so here the description thereof is omitted.

Depending on the circumstances, the conductive paste does not need to be photosensitive. When the conductive paste is not photosensitive, the chemical reaction caused by irradiation proceeds only in the boron paste. However, in the development process it is possible to use the remaining boron paste as a so-called resist to form a pattern in the conductive paste. If the conductive paste readily dissolves in the developer, it will be removed under the same principles as wet etching, and a predetermined pattern is formed thereby. If the conductive paste does not dissolve or dissolves poorly in the developer, after the boron paste has been developed, etching of the conductive paste is performed using the remaining boron paste as a substitute for resist. The etching can be wet etching or dry etching. Even if part of the boron paste is removed during etching, preferably enough boron paste will remain to inhibit oxidation of the conductive component during firing. Because the conductive layer imparts functionality to the electrode, the electrode will continue function effectively provided the functionality of the conductive layer does not decrease.

The present invention is applicable to electronic devices that have an electrode, but the use is not particularly limited thereto. Preferably, the present invention is applicable to an electrode of the rear panel of a PDP (address electrode and/or bus electrode). The production cost of a PDP can be reduced by using the present invention.

### EXAMPLES

The invention is illustrated in further detail below by examples. The examples are for illustrative purposes only, and are not intended to limit the invention.

### Example 1

### 1. Preparation of Organic Components

Texanol (2,2,4-trimethyl-1,3-pentanediol monoisobutyrate) as the solvent and acrylic polymer binder having a molecular weight of 6,000 to 7,000 as the organic binder were mixed, and the mixture was heated to 100° C. while stirring. The mixture was heated and stirred until all of the organic binder had dissolved. The resulting solution was cooled to 75° C. EDAB (ethyl 4-dimethyl aminobenzoate), DETX (diethylthioxanthone), and Irgacure 907 by Chiba Specialty Chemicals were added as photo polymerization initiator, and TAOBN (1,4,4-trimethyl-2,3-diazabicyclo[3.2.2]-non-2-ene-N,N-dixoide) was added as a stabilizer. The mixture was stirred at 75° C. until all the solids had dissolved. The solution was filtered through a 40 micron filter and cooled.

### 2. Preparation of Paste

### 2-1: Preparation of Paste 1 (Cu)

A photopolymerization monomer consisting of 2.62 wt % TMPEOTA (trimethylolpropane ethoxytriacrylate), 2.62 wt % Laromer® LR8967 (polyethyl acrylate oligomer) by BASF and 7.85 wt % Sartomer® SR399E (dipentaerythritol pentaacrylate), 0.84 wt % malonic acid as a stabilizer, 0.17 wt % silicone antifoamer (BYK Chemie, BYK085), 5.91 wt % of additional Texanol solvent, were mixed with 19.50 wt % of the above organic component in a mixing tank under yellow light to prepare a paste. 1.07 wt % bismuth fit (Nippon Yamamura Glass) was used as the glass fit, and 59.43 wt % copper powder (DOWA electronics, D50=1.0 μm) was used as the conductive (metal) particles. The entire paste was mixed until the particles of the inorganic material were wet with the organic material. The mixture was dispersed using a 3-roll mill. The recipe of the paste is shown in Table 2.

### 2-2. Preparation of Paste 2 (B)

A photopolymerization monomer consisting of 6.17 wt % TMPEOTA (trimethylolpropane ethoxytriacrylate), 6.17 wt % Laromer® LR8967 (polyethyl acrylate oligomer) by BASF and 18.50 wt % Sartomer® SR399E (dipentaerythritol pentaacrylate), 1.97 wt % malonic acid as a stabilizer, 0.4 wt % silicone antifoamer (BYK Chemie, BYK085), 5.63 wt % of additional Texanol solvent, were mixed with 45.99 wt % of the above organic component in a mixing tank under yellow light to prepare a paste. 0.28 wt % bismuth fit (Nippon Yamamura Glass) and 14.89 wt % boron powder (H. C. Starck, Boron Amorphous I, D50=0.9 μm) were mixed until the particles of the inorganic material were wet with the organic material. The mixture was dispersed using a 3-roll mill. The recipe of the paste is shown in Table 2.

### 2-3. Preparation of Paste 3 (Cu)

A copper paste was manufactured based on the manufacturing method of Paste 1. The components and the content are as shown in Table 2.

### 2-4. Preparation of Paste 4 (Ni)

A nickel paste was manufactured based on the manufacturing method of Paste 1. The components and the content are as shown in Table 2.

TABLE 2

| | Paste 1 | | Paste 3 | Paste 4 |
|---|---|---|---|---|
| | (Cu) | Paste 2 (B) | (Cu) | (Ni) |
| Medium (binder, initiator, solvent) | 19.50 | 45.99 | 19.50 | 19.50 |
| Antifoamer (silicone oil) | 0.17 | 0.4 | 0.17 | 0.17 |
| Malonic acid (viscosity stabilizer) | 0.84 | 1.97 | 0.84 | 0.84 |
| Solvent (Texanol) | 5.91 | 5.63 | 5.91 | 5.91 |
| Monomer | 13.08 | 30.84 | 13.08 | 13.08 |
| (TMPEOTA:Laromer ®LR8967:Sartomer ® | | | | |
| SR399 = 1:1:3) | | | | |
| Glass frit (Nippon Yamamura Glass) | 1.07 | 0.28 | 1.07 | 1.07 |
| Boron (H. C. Starck, Grade I) | | 14.89 | | |
| Copper (DOWA electronics, | 59.43 | | | |
| D50 = 1.0 μm) | | | | |
| Copper (DOWA electronics, D50 = 0.7 μm) | | | 59.43 | |
| Nickel (JFE Mineral, D50 = 0.4 μm) | | | | 59.43 |
| Total | 100.00 | 100.00 | 100.00 | 100.00 |

### 3. Preparation of Electrodes

Precautions were taken to avoid dirt contamination, as contamination by dirt during the preparation of the paste and the manufacture of the parts would have resulted in defects.

### 3-1: Coating

Paste 1 (Cu) was applied to a glass substrate by screen printing using a 150 to 400 mesh screen. Suitable screen and viscosity of the electrode paste were selected to ensure the desired film thickness was obtained. The paste was then dried for 20 minutes at 100° C. in a hot air circulating furnace.

The same process was carried out by using Paste 2 (B), and a boron layer was formed on top of the copper layer. The combined thickness of the copper layer and the boron layer was 9.3 μm.

### 3-2: UV Ray Pattern Exposure for Photo Patternable Paste.

The dried paste was exposed to UV light through a photo tool using a collimated UV radiation source (illumination: 18 to 20 mW/cm²; exposure: 10-2000 mJ/cm²).

### 3-3: Development for Photo Patternable Paste.

An exposed sample was placed on a conveyor and then placed in a spray developing device filled with 0.4 wt % sodium carbonate aqueous solution as the developer. The developer was kept at a temperature of 30° C., and was sprayed at 10 to 20 psi.

The developing time was decided in the following manner. First, the time to remove a dried unexposed film from the substrate in the developer (TTC, Time To Clear) was measured by printing dried parts under the same conditions as for a pattern-exposed sample. Next, pattern-exposed parts were developed at a developing time set to 1.5 times TTC.

The developed sample was dried by blowing off the excess water with an air jet.

Two methods were used to form a bilayer structure: a case wherein the operation from coating through drying was performed twice, and then the bilayer structure was exposed and developed as a single unit; and a case wherein the bottom layer was coated, exposed, and developed, and then the top layer was coated and firing was carried out.

### 3-4: Sintering

A peak temperature of 590° C. was reached (first sintering) by sintering in a belt furnace in air using a 1.5 hour profile.

The surface resistance, volume resistivity, and the photo patterning in the obtained patterns were evaluated.

To determine the surface resistance of a fired part, first the sample forming the lower layer was printed with screen mask (poly380) with openings of 40 mm square. The part was dried; the top layer was printed again, and dried. Terminals were applied diagonally across the fired part, and the resistance was measured.

For volume resistivity, a photomask with a pattern having a line width of 400 μm and a length of 14.7 mm was used to expose a pattern, and after development and firing, the resistance was measured using the formed pattern, and the volume resistivity was calculated from the line width and film thickness after firing.

Photo patterning was evaluated by the following method. First, it was verified visually whether or not the lines remained on a pattern-exposed part after development. More specifically, when a part coated to have a 3-5 μm fired film thickness was exposed at 800 mJ/cm² and then developed at a development time set at 1.5 times TTC, the photo patterning was judged to be OK if 100 μm lines remained, but if 100 μm lines had been washed away or many broken lines were observed, then the photo patterning was judged to be no good (NG).

### Comparative Examples 1-6

Pattern formation was attempted using Paste 1 and Paste 2 as shown in Table 3. Surface resistance, volume resistivity, and photo patterning were evaluated by the above methods. The results are shown in Table 3.

TABLE 3

| | | Comparative | Comparative | Comparative | Comparative | Comparative | Comparative |
|---|---|---|---|---|---|---|---|
| | Ex. 1 | Ex. 1 | Ex. 2 | Ex. 3 | Ex. 4 | Ex. 5 | Ex. 6 |
| Top Layer | Paste 2 (B) | None | None | Paste 1 (Cu) | None | None | None |
| Bottom Layer | Paste 1 (Cu) | Paste 1 (Cu) | Paste 2 (B) | Paste 2 (B) | Paste 1 (Cu) + | Paste 1 (Cu) + | Paste 1 (Cu) + |
| | | | | | Paste 2 (B) | Paste 2 (B) | Paste 2 (B) |
| | | | | | (B: 12.5 wt %) | (B: 25 wt %) | (B: 50 wt %) |
| Thickness of dried | 9.3 | 5 | 5.4 | 10.2 | 10 | 10.1 | 10.1 |
| film (um) | | | | | | | |
| Surface resistance | 0.279 | 436000 | N/M | N/M | 1320000 | 164 | N/M |
| Ohm | | | | | | | |
| Volume resistivity | 1.88E−05 | 1.08E+02 | N/M | N/M | 1.99E+02 | 6.16E−04 | N/M |
| Ohm · cm | | | | | | | |
| Photo patterning | OK | OK | OK | OK | OK | OK | OK |

N/M: not measurable

Example 1 in Table 3 shows the results when first a bottom layer was formed with copper paste, and after drying, boron paste was coated and dried, and then the part was exposed, developed, and fired. In this case, the external appearance of the fired film was brown, and it exhibited relatively low resistance values with a surface resistance of 0.279Ω and a volume resistivity of 1.88×10⁻⁵ Ohm·cm.

Comparative Examples 1 and 2 show the results when the copper paste and boron paste constituting Example 1 were each formed alone without layering. The patterning properties resulting from development after UV exposure were good in both Comparative Examples 1 and 2. However, in Comparative Example 1, wherein a film comprising only copper paste was air fired, the appearance after firing showed the black color of copper oxide (CuO), and both the surface resistance and volume resistivity were conspicuously greater than in Example 1. Comparative Example 2, wherein a film comprising only boron paste was air fired, was an insulator with both surface resistance and volume resistivity greater than the upper limit of measurement (100 MΩ).

In Comparative Example 3 the copper paste exhibiting low resistance in Example 1 and the boron paste were inverted such that the boron paste formed the bottom layer and the copper paste formed the top layer. In this case the patterning due to UV exposure was good, but after firing the film exhibited the black color of copper oxide (CuO), and because the film had lifted off the glass substrate, resistance could not be measured.

Thus, it is clear that the low resistance values obtained after air firing in Example 1 were achieved by a configuration wherein a conductive paste (in this case, copper) and a boron paste are applied to form bottom and top layers, respectively.

Additionally, Comparative Examples 4, 5, and 6 are cases wherein the paste 1 (copper paste) and the paste 2 (boron paste) were mixed together beforehand and coated. At that time, the same paste was coated twice to reach a film thickness roughly approaching that of Example 1.

In this case, the mixtures were prepared so that the percentage by weight of [boron]/[boron+copper] in the mixed paste was 12.5 wt % for Comparative Example 4, 25 wt % for Comparative Example 5, and 50 wt % for Comparative Example 6.

In each of Comparative Examples 4, 5, and 6 it was possible to form patterns by UV light irradiation. In Comparative Example 4 the fired film appeared somewhat darkly discolored, and the resistance was conspicuously large. The resistance in Comparative Example 6 was greater than the upper limit of measurement. In Comparative Example 5 a somewhat low resistance value was obtained, but that value was still markedly greater than in Example 1. From the above it was clear that there are cases such as in Example 1 wherein a lower resistance value is obtained by forming a bilayer structure from pastes with different configurations, i.e., conductor and boron, than by merely mixing the two together.

### Examples 2-5

### Comparative Examples 7-8

Pattern forming was attempted using Paste 2 (B), Paste 3 (Cu), and Paste 4 (Ni) shown in Table 1.

TABLE 4

| | | | Comparative | Comparative | | |
|---|---|---|---|---|---|---|
| | Ex. 2 | Ex. 3 | Ex. 7 | Ex. 8 | Ex. 4 | Ex. 5 |
| Top Layer | Paste 2 (B) | Paste 2 (B) | None | None | Paste 2 (B) | Paste 2 (B) |
| Bottom Layer | Paste 3 (Cu) | Paste 4 (Ni) | Paste 3 (Cu) | Paste 4 (Ni) | Paste 3 (Cu) | Paste 4 (Ni) |
| Thickness of dried film | 11.75 | 11.4 | 5.2 | 5 | 9.3 | 5 |
| (um) | | | | | | |
| Surface resistance Ohm | 0.195 | 4.585 | 911500 | 4.00E+07 | — | — |
| Volume resistivity Ohm · cm | 1.28E−05 | 6.98E−04 | N/M | N/M | 2.21E−05 | 5.31E−04 |
| Photo patterning | OK | OK | — | — | OK | OK |

For Examples 2 and 3 in Table 4, the bottom layer was configured by coating and drying a paste containing copper or nickel conductive powder, respectively, and after a paste containing boron was coated as the top layer, the bilayer dried films were exposed and developed. In this case the cross-sectional structure of the formed pattern is the one illustrated in FIG. 1. In Example 2 the surface resistance was 0.195Ω and the volume resistivity was 1.28×10⁻⁵ Ω·cm, and in Example 3 the surface resistance was 4.585Ω and the volume resistivity was 6.98×10⁻⁴ Ω·cm. These values were conspicuously lower than cases wherein no boron was in the top layer, i.e., Comparative Examples 7 and 8, and the effect of decreased resistance due to a top layer of boron-containing film is clearly illustrated.

Examples 4 and 5 in Table 4 are cases wherein a paste containing copper or nickel, respectively, was coated and dried as a bottom layer, and exposed and developed to form a pattern, and then a paste containing boron was coated to the entire surface as an upper layer, dried, and fired. In this case, the cross-structure of the formed patterns is the one illustrated in FIG. 3. In Examples 4 and 5 the volume resistivity was 2.21×10⁻⁵ Ω·cm and 5.31×10⁻⁴ Ω·cm, respectively, and in the structure shown in FIG. 3, and the effect of decreased resistance due to a top layer of boron-containing film is clearly illustrated.

### Examples 6-8

### Comparative Examples 9-11

Pattern forming was attempted using Paste 5 (Cu+Sn), Paste 6 (Bi+Sn), Paste 7 (Cu+solder), and Paste 8 (B) shown in Table 5.

TABLE 5

| | Paste 5 | Paste 6 | Paste 7 | Paste 8 |
|---|---|---|---|---|
| | (Cu + Sn) | (Bi + Sn) | (Cu + Solder) | (B) |
| Medium (binder, initiator, solvent) | 18.00 | 13.17 | 13.17 | 42.76 |
| Antifoamer (silicone oil) | | | | 0.38 |
| Dispersant (Soya lecithin) | 0.58 | 0.61 | 0.61 | |
| Malonic acid (viscosity stabilizer) | | | | 1.83 |
| Solvent (Texanol) | 0.45 | 0.48 | 0.48 | 5.24 |
| Monomer | | | | 28.76 |
| (TMPEOTA:Laromer ® LR8967:Sartomer ® | | | | |
| SR399 = 1:1:3) | | | | |
| Glass frit (Nippon Yamamura Glass) | 2.90 | 3.07 | 3.07 | 0.26 |
| Boron (H. C. Starck, Grade I) | | | | 20.77 |
| Braze Tec CTF600, Cu 76, Sn 15, Ni 4, | 78.07 | | | |
| P 5 Alloy in a form of thermoplastic | | | | |
| paste, Tm 590-600 C | | | | |
| Mitsui Kinzoku, Sn42%/Bi58% alloy, | | 82.68 | | |
| 5um powder | | | | |
| Mitsui Kinzoku, SAC305, | | | 41.34 | |
| Sn96.5%/Ag 3% Cu 0.5%, Pb-free | | | | |
| solder alloy, 5um powder | | | | |
| Copper (DOWA electronics, D50 = 1.0 μm) | | | 41.34 | |
| Total | 100.00 | 100.00 | 100.00 | 100.00 |

Resistance was measured in the fired films prepared by configuring a conductive layer using pastes containing the various metals shown in Table 5 and combining that with a top layer of boron-containing paste as shown in Table 6. It is clear that the configuration of the present invention imparted lower resistance in relation to the various types of metals than when the conductor alone was fired.

TABLE 6

| | | | | Comparative | Comparative | Comparative |
|---|---|---|---|---|---|---|
| | Ex. 6 | Ex. 7 | Ex. 8 | Ex. 9 | Ex. 10 | Ex. 11 |
| Top Layer | Paste 8 (B) | Paste 8 (B) | Paste 8 (B) | None | None | None |
| Bottom Layer | Paste 5 | Paste 6 | Paste 7 | Paste 5 | Paste 6 | Paste 7 |
| | (Cu + Sn) | (Bi + Sn) | (Cu + Solder) | (Cu + Sn) | (Bi + Sn) | (Cu + Solder) |
| Thickness of dried film (um) | 45.6 | 36.5 | 27.6 | 36.8 | 28.2 | 21.2 |
| Surface resistance Ohm | 9.865 | 1200 | 1.462 | 7980000 | >1E+08 | 17323 |

What is claimed is:

1. An electrode comprising:
a conductive layer, prior to firing, containing a photosensitive conductive paste containing a conductive component selected from the group consisting of copper, nickel, iron, cobalt, titanium, lead, aluminum, tin, and alloys comprising one of these metals as the principal ingredient thereof; and
an oxidation protection layer containing boron oxide and covering the top surface of said conductive layer or covering the top and sides of said conductive layer or covering all locations of the conductive layer where-ever the conductive layer has been formed;
said electrode being formed by air firing said conductive layer and said oxidation protection layer simultaneously.

2. The electrode according to claim 1, wherein said oxidation protection layer covers both the top surface and the sides of said conductive layer.

3. The electrode according to claim 1, wherein said oxidation protection layer covers all locations where said conductive layer has been formed.

4. The electrode according to claim 1, wherein the electrode is formed on a glass substrate.

5. The electrode according to claim 1, wherein the electrode is formed on a rear glass substrate of PDP.

6. An electrode comprising:
a conductive layer containing a conductive component selected from the group consisting of copper, nickel, iron, cobalt, titanium, lead, aluminum, and alloys comprising one of these metals as the principal ingredient thereof; and
an oxidation protection layer, prior to firing, containing photosensitive paste containing boron and covering the top surface of said conductive layer or covering the top and sides of said conductive layer or covering all locations of the conductive layer where-ever the conductive layer has been formed;
said electrode being formed by air firing said conductive layer and said oxidation protection layer simultaneously.

7. The electrode according to claim 6, wherein said oxidation protection layer covers both the top surface and the sides of said conductive layer.

8. The electrode according to claim 6, wherein said oxidation protection layer covers all locations where said conductive layer has been formed.

9. The electrode according to claim 6, wherein the electrode is formed on a glass substrate.

10. The electrode according to claim 6, wherein the electrode is formed on a rear glass substrate of PDP.

11. A method for manufacturing an electrode, comprising the steps of:
coating a photosensitive conductive paste containing a conductive component selected from the group consisting of copper, nickel, iron, cobalt, titanium, lead, aluminum, tin, and alloys comprising one of these metals as the principal ingredient thereof, onto a substrate;
exposing said coated conductive paste in a predetermined pattern;
developing said exposed conductive paste;
coating a boron paste containing boron powder on top of said developed conductive paste;
drying said boron paste; and
air firing said conductive paste and boron paste.

12. The method for manufacturing an electrode according to claim 11, wherein said boron paste is coated in a pattern identical to the coating pattern of said conductive paste.

13. The method for manufacturing an electrode according to claim 11, wherein said boron paste is coated in a wider pattern than the coating pattern of said conductive paste, and part of the coated boron paste covers the sides of said conductive paste.

14. The method for manufacturing an electrode according to claim 11, wherein said boron paste is coated to cover all locations on which said conductive paste has been coated.

15. A method for manufacturing an electrode, comprising the steps of:
coating a conductive paste containing a conductive component selected from the group consisting of copper, nickel, iron, cobalt, titanium, lead, aluminum, tin, and alloys comprising one of these metals as the principal ingredient thereof, onto a substrate;
drying said coated conductive paste;
coating a photosensitive boron paste containing boron powder on top of said dried conductive paste;
exposing said coated photosensitive boron paste in a predetermined pattern;
developing said conductive paste and exposed boron paste; and
air firing said conductive paste and said boron paste.
